(19) United States
(12) Patent Application Publication
(10) Pub. No.: US 2025/0151565 A1
(43) Pub. Date: May 8, 2025

(54) COLOR CONVERSION SUBSTRATE AND DISPLAY DEVICE INCLUDING THE SAME

(71) Applicant: Samsung Display Co., LTD., Yongin-si, Gyeonggi-do (KR)

(72) Inventors: SEON UK LEE, Yongin-si (KR); SUNKWANG KIM, Yongin-si (KR); SOO-LIN KIM, Yongin-si (KR)

(21) Appl. No.: 18/412,080

(22) Filed: Jan. 12, 2024

(30) Foreign Application Priority Data
Jan. 17, 2023 (KR) 10-2023-0006615

(51) Int. Cl. H10K 59/38; H10K 59/35

(52) U.S. Cl. CPC H10K 59/38; H10K 59/353

(57) ABSTRACT

A color conversion substrate includes a substrate including a first sub-pixel area, a second sub-pixel area, and a third sub-pixel area configured to emit light of different respective colors, and spaced apart from each other in a first direction, wherein each of the first sub-pixel area and the second sub-pixel area has a right-angled triangle shape in which at least one of corners other than a corner forming a right angle is chamfered, and wherein the third sub-pixel area has a quadrilateral shape.

### CROSS-REFERENCE TO RELATED APPLICATION

This application claims priority to, and the benefit of, Korean Patent Application No. 10-2023-0006615, filed on Jan. 17, 2023, in the Korean Intellectual Property Office, the content of which in its entirety is herein incorporated by reference.

### BACKGROUND

### 1. Field

The disclosure relates to a color conversion substrate including a color conversion layer, and to a display device including the color conversion substrate.

### 2. Description of the Related Art

A display device is a device that displays an image to provide visual information to a user. Among display devices, an organic light-emitting diode display (OLED display) has recently been attracting attention.

The display device may include an array substrate that emits light, and a color conversion substrate that converts and transmits the light. The array substrate may include driving elements and light-emitting diodes located on the driving elements.

The driving elements generate a driving current, and the light-emitting diodes emit light by receiving the driving current. The color conversion substrate may include a color conversion layer including color conversion patterns. The color conversion layer may convert or selectively transmit light generated from the array substrate.

### SUMMARY

Embodiments provide a color conversion substrate with improved coloration.

Embodiments provide a display device including the color conversion substrate.

A color conversion substrate according to one or more embodiments may include a substrate including a first sub-pixel area, a second sub-pixel area, and a third sub-pixel area configured to emit light of different respective colors, and spaced apart from each other in a first direction, wherein each of the first sub-pixel area and the second sub-pixel area has a right-angled triangle shape in which at least one of corners other than a corner forming a right angle is chamfered, and wherein the third sub-pixel area has a quadrilateral shape.

The first sub-pixel area, the second sub-pixel area, and the third sub-pixel area may overlap each other in the first direction.

A hypotenuse of the first sub-pixel area and a hypotenuse of the second sub-pixel area may be adjacent to each other.

The first sub-pixel area may include a first side and a second side that are substantially perpendicular to each other, a length of the first side being greater than or equal to a length of the second side, wherein the second sub-pixel area includes a third side and a fourth side that are substantially perpendicular to each other, a length of the third side being greater than or equal to a length of the fourth side.

The first side and the third side may be substantially parallel to each other, wherein the second side and the fourth side are substantially parallel to each other.

The fourth side may be spaced apart from the first side in a second direction crossing the first direction in plan view.

The second side may be spaced apart from the third side in a direction opposite to the second direction in plan view.

The third sub-pixel area may have a rectangular shape.

An area of the first sub-pixel area may be greater than or equal to an area of the second sub-pixel area, wherein the area of the second sub-pixel area is greater than an area of the third sub-pixel area.

The first sub-pixel area may be configured to emit a first light having a red color, wherein the second sub-pixel area is configured to emit a second light having a green color, and wherein the third sub-pixel area is configured to emit a third light having a blue color.

A center of the third sub-pixel area may overlap a center of a collective pixel area of the first to third sub-pixel areas in the first direction.

The color conversion may further include a partition wall under the substrate, and defining the first sub-pixel area, the second sub-pixel area, and the third sub-pixel area.

A width of the partition wall between the first sub-pixel area and the second sub-pixel area, and a width of the partition wall between the second sub-pixel area and the third sub-pixel area, may be about 5 micrometers to about 20 micrometers.

The color conversion may further include a color conversion layer below the substrate, and overlapping the first sub-pixel area, the second sub-pixel area, and the third sub-pixel area in plan view.

The color conversion layer may include a first color conversion pattern overlapping the first sub-pixel area, a second color conversion pattern overlapping the second sub-pixel area, and a transmission pattern overlapping the third sub-pixel area.

The color conversion may further include a color filter layer between the substrate and the color conversion layer.

The first to third pixel areas may further include a light-blocking area surrounding the first to third sub-pixel areas, wherein the color filter layer includes first to third color filter layers partially overlapping each other, wherein the first color filter layer includes a first color filter pattern overlapping the first sub-pixel area, and not overlapping the second color filter layer and the third color filter layer, wherein the second color filter layer includes a second color filter pattern overlapping the second sub-pixel area, and not overlapping the first color filter layer and the third color filter layer, and the third color filter layer includes a third color filter pattern overlapping the third sub-pixel area, and not overlapping the first color filter layer and the second color filter layer.

An area of the first color filter pattern may be greater than an area of the second color filter pattern, wherein the area of the second color filter pattern is greater than an area of the third color filter pattern.

An area of the first color filter pattern may be less than an area of the first sub-pixel area, wherein an area of the second color filter pattern is less than an area of the second sub-pixel area, and wherein an area of the third color filter pattern is less than an area of the third sub-pixel area.

A color conversion substrate according to one or more other embodiments may include a substrate including a substrate including a first sub-pixel area, a second sub-pixel area, and a third sub-pixel area configured to emit light of different respective colors, and spaced apart from each other in a first direction, wherein each of the first sub-pixel area and the third sub-pixel area has a trapezoidal shape, and wherein the second sub-pixel area is spaced from each of the first sub-pixel area and the third sub-pixel area.

The first sub-pixel area, the second sub-pixel area, and the third sub-pixel area may overlap each other in the first direction.

The second sub-pixel area may have a trapezoidal shape.

Each of the first sub-pixel area and the third sub-pixel area may have a trapezoidal shape, a width of which becomes narrower toward a second direction crossing the first direction, wherein the second sub-pixel area has a trapezoidal shape, a width of which becomes wider toward the second direction.

A display device according to one or more embodiments may include a color conversion substrate including a first substrate including a first sub-pixel area, a second sub-pixel area, and a third sub-pixel area configured to emit light of different respective colors, and spaced apart from each other in a first direction, and an array substrate including a second substrate facing the first substrate, and including light-emitting diodes on the second substrate and respectively overlapping the first to third sub-pixel areas, wherein each of the first sub-pixel area and the second sub-pixel area has a right-angled triangle shape in which at least one of corners, other than a corner forming a right angle, is chamfered, and wherein the third sub-pixel area has a quadrilateral shape.

The first sub-pixel area, the second sub-pixel area, and the third sub-pixel area may overlap each other in the first direction.

A hypotenuse of the first sub-pixel area and a hypotenuse of the second sub-pixel area may be adjacent to each other.

The first sub-pixel area may include a first side and a second side that are substantially perpendicular to each other, a length of the first side being greater than or equal to a length of the second side, wherein the second sub-pixel area includes a third side and a fourth side that are substantially perpendicular to each other, a length of the third side being greater than or equal to a length of the fourth side.

The first side and the third side may be substantially parallel to each other, wherein the second side and the fourth side are substantially parallel to each other.

The third sub-pixel area may have a rectangular shape.

The color conversion substrate may further include a partition wall under the first substrate, and defining the first sub-pixel area, the second sub-pixel area, and the third sub-pixel area, a color conversion layer below the first substrate, and overlapping the first sub-pixel area, the second sub-pixel area, and the third sub-pixel area, and a color filter layer between the first substrate and the color conversion layer.

Each of the first to third pixel areas may further include a light-blocking area surrounding the first to third sub-pixel areas, wherein the color filter layer includes first to third color filter layers partially overlapping each other, wherein the first color filter layer includes a first color filter pattern overlapping the first sub-pixel area, and not overlapping the second color filter layer and the third color filter layer, wherein the second color filter layer includes a second color filter pattern overlapping the second sub-pixel area, and not overlapping the first color filter layer and the third color filter layer, and wherein the third color filter layer includes a third color filter pattern overlapping the third sub-pixel area, and not overlapping the first color filter layer and the second color filter layer.

The light-emitting diodes may include a first light-emitting diode overlapping the first sub-pixel area, a second light-emitting diode overlapping the second sub-pixel area, and a third light-emitting diode overlapping the third sub-pixel area.

The first light-emitting diode may include a first pixel electrode overlapping the first sub-pixel area, wherein the second light-emitting diode includes a second pixel electrode overlapping the second sub-pixel area, and wherein the third light-emitting diode includes a third pixel electrode overlapping the third sub-pixel area.

An area of the first pixel electrode may be less than an area of the first color filter pattern, wherein an area of the second pixel electrode is less than an area of the second color filter pattern, and wherein an area of the third pixel electrode is less than an area of the third color filter pattern.

In the display device according to embodiments, as a color conversion substrate includes first to third sub-pixel areas overlapping each other in a first direction, an overlapping area of the three sub-pixel areas in the first direction may increase. Accordingly, a color phenomenon in which upper and lower edges in a pixel area are displayed in green or magenta instead of white may be improved. In addition, as each of the first sub-pixel area and the second sub-pixel area have a shape in which a width becomes narrower or wider toward the second direction, luminous efficiency of the display device may be increased.

In addition, because the third sub-pixel area has a rectangular shape, it is possible to easily correct misplaced shots. As a result, efficiency in the manufacturing process of the display device may be improved.

It is to be understood that both the foregoing general description and the following detailed description are explanatory, and are intended to provide further explanation of the claimed embodiments.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to one or more embodiments.

FIG. 2 is a cross-sectional view taken along the line I-I′ of FIG. 1.

FIG. 3 is a plan view illustrating a portion of the color conversion substrate of FIG. 2.

FIG. 4 is an enlarged plan view of one pixel area of FIG. 3.

FIG. 5 is a cross-sectional view taken along the line II-II′ of FIG. 4.

FIG. 6 is a plan view illustrating only the color conversion layer and the color filter layer of FIG. 5.

FIG. 7 is an enlarged cross-sectional view of a portion of the display device of FIG. 2.

FIG. 8 is a plan view illustrating only the color conversion layer, color filter layer, and pixel electrodes of FIG. 7.

FIG. 9 is a plan view illustrating another example of FIG. 4.

FIG. 10 is a plan view illustrating still another example of FIG. 4.

FIG. 11 is a cross-sectional view illustrating another example of FIG. 7.

FIG. 12 is a block diagram illustrating an electronic device according to embodiments.

FIG. 13 is a diagram illustrating a case in which the electronic device of FIG. 12 is implemented as a monitor.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

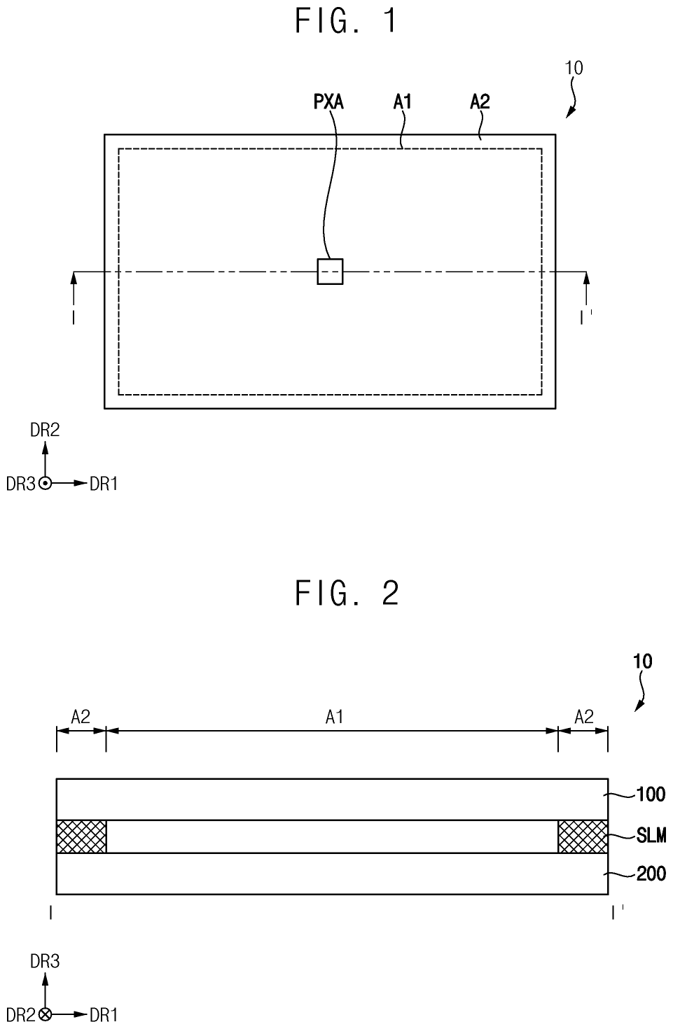

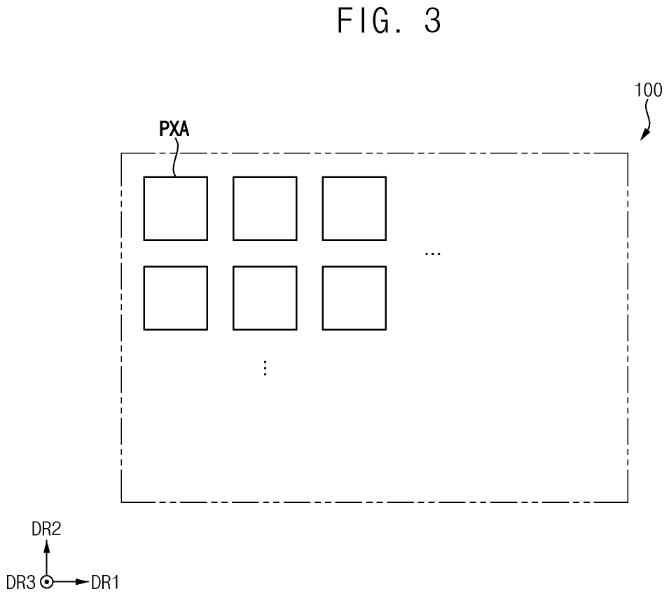

FIG. 1 is a plan view illustrating a display device according to one or more embodiments. FIG. 2 is a cross-sectional view taken along the line I-I′ of FIG. 1.

Referring to FIGS. 1 and 2, the display device 10 may include a color conversion substrate 100, a sealing member SLM, and an array substrate 200. The color conversion substrate 100 may face the array substrate 200. Each of the color conversion substrate 100 and the array substrate 200 may include a plane formed by a first direction DR1 and a second direction DR2. The second direction DR2 may intersect the first direction DR1.

The color conversion substrate 100 may be in a third direction DR3 from the array substrate 200. For example, the third direction DR3 may intersect the first direction DR1 and the second direction DR2, and may be a front direction of the display device 10 from the array substrate 200. The sealing member SLM may be between the array substrate 200 and the color conversion substrate 100. The sealing member SLM may bond the array substrate 200 and the color conversion substrate 100.

The display device 10 may include a first area A1 where an image is displayed, and a second area A2 surrounding (e.g., in plan view) the first area A1. For example, the first area A1 may be a display area, and the second area A2 may be a non-display area. For example, the second area A2 may be a sealing area. However, the present disclosure is not limited thereto, and the second area A2 may be a display area like the first area A1.

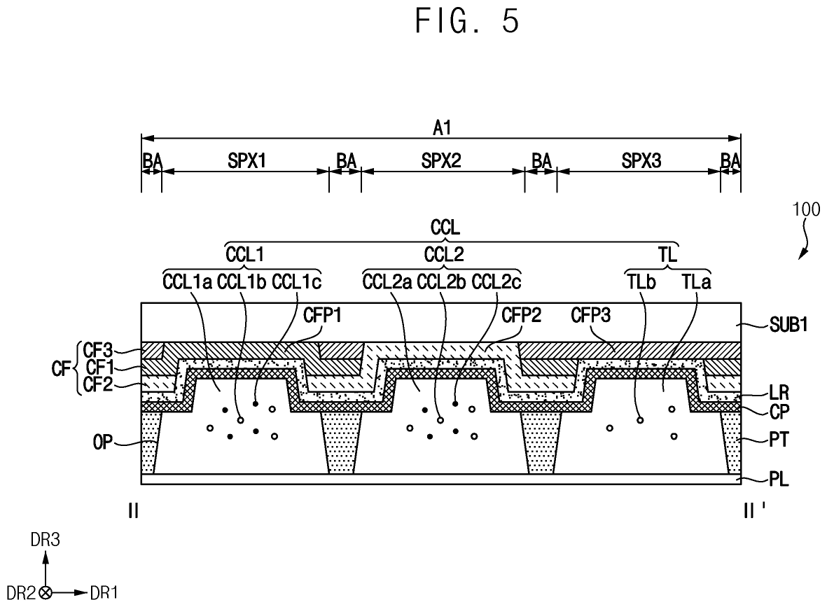

The color conversion substrate 100 may include a color conversion layer (e.g., a color conversion layer CCL of FIG. 5). The color conversion layer may be in the first area A1, and may convert a wavelength of light generated from light-emitting diodes of the array substrate 200. The color conversion substrate 100 may further include a color filter layer (e.g., a color filter layer CF of FIG. 5) that transmits light of a corresponding color.

The array substrate 200 may include a plurality of pixels PX, and may be referred to as a display substrate. The pixels PX may be in the first area A1 of the array substrate 200. Each of the pixels PX may include a driving element and a light-emitting diode. The driving element may include at least one thin film transistor. The light-emitting diode may generate light according to a driving signal. For example, the light-emitting diode may be an inorganic light-emitting diode or an organic light-emitting diode.

The sealing member SLM may be between the array substrate 200 and the color conversion substrate 100, and may be in the second area A2. For example, the sealing member SLM may be in the second area A2 between the array substrate 200 and the color conversion substrate 100 to surround the first area A1 in a plan view.

For example, the sealing member SLM may have a hollow rectangular planar shape (e.g., in plan view). However, the present disclosure is not limited thereto, and the sealing member SLM may have various planar shapes according to a planar shape of the array substrate 200 or the color conversion substrate 100. For example, when the array substrate 200 or the color conversion substrate 100 has a planar shape, such as a triangle, a rhombus, a circle, or an ellipse, the sealing member SLM may have a planar shape, such as a hollow triangle, a hollow rhombus, a hollow circle, or a hollow oval. A filling layer may be between the array substrate 200 and the color conversion substrate 100. For example, the filling layer may act as a buffer against external pressure applied to the display device 10. For example, the filling layer may maintain a gap between the array substrate 200 and the color conversion substrate 100. However, the present disclosure is not limited thereto.

FIG. 3 is a plan view illustrating a portion of the color conversion substrate of FIG. 2.

Referring further to FIG. 3, the color conversion substrate 100 may include a plurality of pixel areas PXA in the first area A1. The pixel areas PXA may be arranged in a regular arrangement along the first direction DR1 and the second direction DR2.

For example, each of the pixel areas PXA may have a quadrilateral shape. However, the present disclosure is not limited thereto, and each of the pixel areas PXA may have various shapes, such as a rectangular shape, a polygonal shape, and a circular shape.

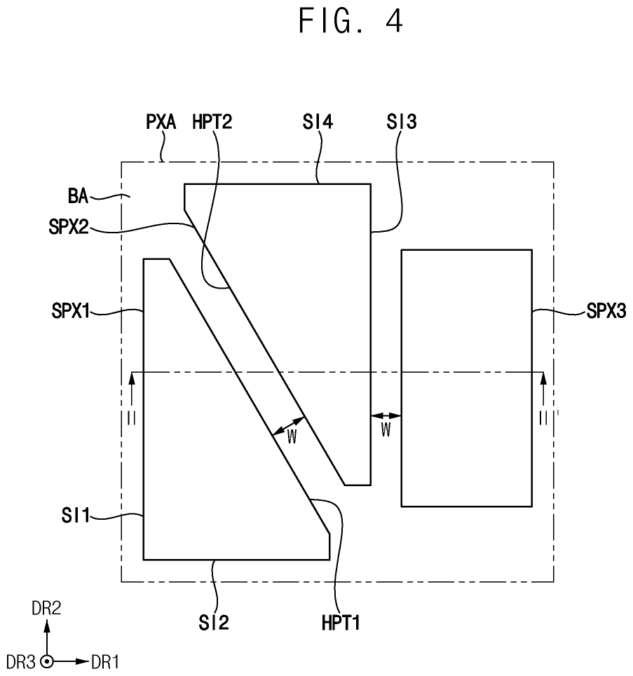

FIG. 4 is an enlarged plan view of one pixel area of FIG. 3.

Referring to FIGS. 3 and 4, each of the pixel areas PXA may include a sub-pixel area and a light-blocking area BA. For example, each of the pixel areas PXA may include a first sub-pixel area SPX1, a second sub-pixel area SPX2, a third sub-pixel area SPX3, and a light-blocking area BA.

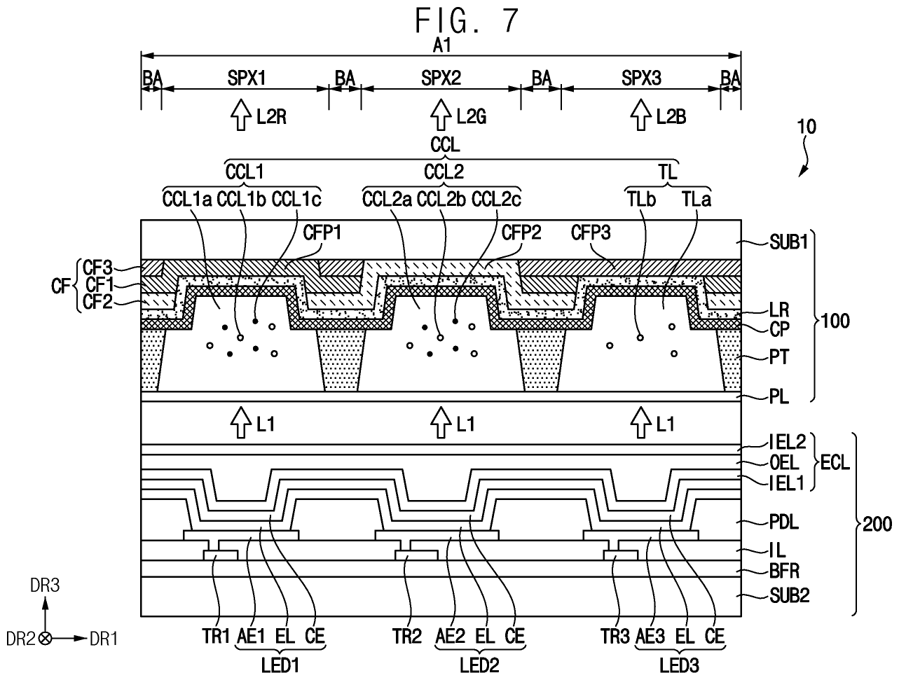

The first sub-pixel area SPX1, the second sub-pixel area SPX2, and the third sub-pixel area SPX3 may emit light of different colors. For example, the first sub-pixel area SPX1 may emit a first light L2R having a red color, the second sub-pixel area SPX2 may emit a second light L2G having a green color, and the third sub-pixel area SPX3 may emit a third light L2B having a blue color (e.g., see FIG. 7). However, the present disclosure is not limited thereto.

The first sub-pixel area SPX1, the second sub-pixel area SPX2, and the third sub-pixel area SPX3 may be spaced apart from each other in a plan view. In addition, as the pixel areas PXA are repeatedly aligned with each other, the first sub-pixel area SPX1, the second sub-pixel area SPX2, and the third sub-pixel area SPX3 may also be arranged to be repeatedly arranged with each other. The light-blocking area BA may surround the first to third sub-pixel areas SPX1, SPX2, and SPX3 in a plan view.

In one or more embodiments, the first sub-pixel area SPX1, the second sub-pixel area SPX2, and the third sub-pixel area SPX3 may be sequentially arranged in the first direction DR1. Also, the first sub-pixel area SPX1, the second sub-pixel area SPX2, and the third sub-pixel area SPX3 may overlap each other in the first direction DR1.

In one or more embodiments, the first sub-pixel area SPX1, the second sub-pixel area SPX2, and the third sub-pixel area SPX3 may entirely overlap each other in the first direction DR1. However, the present disclosure is not limited thereto, and each of the first sub-pixel area SPX1, the second sub-pixel area SPX2, and the third sub-pixel area SPX3 may partially overlap each other in the first direction DR1 (e.g., while also having non-overlapping portions).

In one embodiment, the first sub-pixel area SPX1 may have a right-angled triangle shape in which at least one of corners, other than a corner forming a right angle, is chamfered. Accordingly, the first sub-pixel area SPX1 may include a first hypotenuse HPT1. The first hypotenuse HPT1 may mean a side that is opposite the corner that forms a right angle in the first sub-pixel area SPX1. Also, similarly, the second sub-pixel area SPX2 may have a right-angled triangle shape in which at least one of corners other than a corner forming a right angle is chamfered. The second sub-pixel area SPX2 may include a second hypotenuse HPT2. The second hypotenuse HPT2 may mean a side that is opposite the corner that forms a right angle in the second sub-pixel area SPX2.

In one or more embodiments, the first hypotenuse HPT1 of the first sub-pixel area SPX1 and the second hypotenuse HPT2 of the second sub-pixel area SPX2 may be adjacent to each other. The first hypotenuse HPT1 and the second hypotenuse HPT2 may be entirely spaced apart from each other by a distance (e.g., predetermined distance) W.

As each of the first sub-pixel area SPX1 and the second sub-pixel area SPX2 has a chamfered right-angled triangle shape, when applying ink to each of the first sub-pixel area SPX1 and the second sub-pixel area SPX2, the ink may be applied uniformly as a whole. However, the present disclosure is not limited thereto, and in one or more other embodiments, each of the first sub-pixel area SPX1 and the second sub-pixel area SPX2 may have a right-angled triangle shape. Accordingly, each of the first sub-pixel area SPX1 and the second sub-pixel area SPX2 may include corners having an acute angle.

Also, the first sub-pixel area SPX1 may include a first side SI1 and a second side SI2 that are substantially perpendicular to each other. A length of the first side SI1 may be greater than or equal to a length of the second side SI2. Similarly, the second sub-pixel area SPX2 may include a third side SI3 and a fourth side SI4 that are substantially perpendicular to each other. A length of the third side SI3 may be greater than or equal to a length of the fourth side SI4.

However, the present disclosure is not limited thereto, and in one or more other embodiments, the first side SI1 and the second side SI2 of the first sub-pixel area SPX1 may form an obtuse angle or an acute angle (rather than a right angle) to each other, and the third side SI3 and the fourth side SI4 of the second sub-pixel area SPX2 may form an obtuse angle or an acute angle (rather than a right angle) to each other.

In one or more embodiments, the first side SI1 and the third side SI3 may be substantially parallel to each other. The second side SI2 and the fourth side SI4 may be substantially parallel to each other.

In one or more embodiments, an area obtained by combining the first sub-pixel area SPX1 and the second sub-pixel area SPX2 may have a shape that is similar to a rectangular shape as a whole. In this case, the rectangular shape may be divided by an oblique line crossing the rectangular shape to define a shape of the first sub-pixel area SPX1 and a shape of the second sub-pixel area SPX2.

In one or more embodiments, the first sub-pixel area SPX1 may have a shape in which a width becomes narrower toward the second direction DR2. Unlike this, the second sub-pixel area SPX2 may have a shape in which a width becomes wider toward the second direction DR2.

In one or more embodiments, the fourth side SI4 may be spaced apart from the first side SI1 in the second direction DR2. Also, the second side SI2 may be spaced apart from the third side SI3 in a direction opposite to the second direction DR2. That is, the first sub-pixel area SPX1 may protrude more than the second sub-pixel area SPX2 in a direction opposite to the second direction DR2. Also, the second sub-pixel area SPX2 may protrude more than the first sub-pixel area SPX1 in the second direction DR2. Accordingly, each of the first sub-pixel area SPX1 and the second sub-pixel area SPX2 may secure a larger area. As a result, an opening ratio of the display device 10 may be increased, and thus a light-emitting efficiency of the display device 10 may be increased.

In one or more embodiments, the third sub-pixel area SPX3 may have a quadrilateral shape. For example, the third sub-pixel area SPX3 may have a rectangular shape. That is, the third sub-pixel area SPX3 may have a shape having a constant width along the second direction DR2. Also, a center of the third sub-pixel area SPX3 may be on a line extending in the first direction DR1 passing through a center of the pixel area PXA. That is, the center of the third sub-pixel area SPX3 may overlap the center of the pixel area PXA in the first direction DR1.

In one or more embodiments, a length of the third sub-pixel area SPX3 in the first direction DR1 may be about 55.7 micrometers, and a length of the third sub-pixel area SPX3 in the second direction DR2 may be about 85.5 micrometers. Accordingly, when a transmission pattern (e.g., a transmission pattern TL of FIG. 5) is formed in the third sub-pixel area SPX3 by an inkjet process, two drops of ink may be applied per scan to the third sub-pixel area SPX3. However, the present disclosure is not limited thereto.

In one or more embodiments, an area of the first sub-pixel area SPX1 may be greater than or equal to an area of the second sub-pixel area SPX2. Also, the area of the second sub-pixel area SPX2 may be greater than an area of the third sub-pixel area SPX3.

FIG. 5 is a cross-sectional view taken along the line II-II′ of FIG. 4.

Referring to FIGS. 4 and 5, in one or more embodiments, the color conversion substrate 100 may include a first substrate SUB1, a color filter layer CF, a partition wall PT, a color conversion layer CCL, a low refractive index layer LR, a capping layer CP, and a protective layer PL.

The first substrate SUB1 may include the first area A1 and the second area A2 as the color conversion substrate 100 includes the first area A1 and the second area A2 described above. Also, as the first area A1 includes the pixel areas PXA, the first substrate SUB1 may include the pixel areas PXA.

The first substrate SUB1 may be an insulating substrate formed of a transparent material. The first substrate SUB1 may include glass or plastic.

The color filter layer CF may be under the first substrate SUB1. For example, the color filter layer CF may be under the first substrate SUB1, and may overlap the first area A1 and the second area A2. The color filter layer CF may include a first color filter layer CF1, a second color filter layer CF2, and a third color filter layer CF3. For example, the first color filter layer CF1 may be a red color filter layer, the second color filter layer CF2 may be a green color filter layer, and the third color filter layer CF3 may be a blue color filter layer. However, the present disclosure is not limited thereto.

The first color filter layer CF1 may overlap the first sub-pixel region SPX1, and may selectively transmit a red light. The second color filter layer CF2 may overlap the second sub-pixel area SPX2, and may selectively transmit a green light. The third color filter layer CF3 may overlap the third sub-pixel area SPX3, and may selectively transmit a blue light.

In one or more embodiments, each of the first color filter layer CF1, the second color filter layer CF2, and the third color filter layer CF3 may further overlap with the light-blocking area BA. That is, the first color filter layer CF1, the second color filter layer CF2, and the third color filter layer CF3 may partially overlap each other.

For example, the first color filter layer CF1 may overlap the first sub-pixel area SPX1 and the light-blocking area BA, and may not overlap the second sub-pixel area SPX2 and the third sub-pixel area SPX3. A portion of the first color filter layer CF1 that does not overlap with the second color filter layer CF2 and the third color filter layer CF3 may be defined as a first color filter pattern CFP1. That is, the first color filter pattern CFP1 may overlap the first sub-pixel area SPX1, and may not overlap the second color filter layer CF2 and the third color filter layer CF3.

The second color filter layer CF2 may overlap the second sub-pixel area SPX2 and the light-blocking area BA, and may not overlap the first sub-pixel area SPX1 and the third sub-pixel area SPX3. A portion of the second color filter layer CF2 that does not overlap with the first color filter layer CF1 and the third color filter layer CF3 may be defined as a second color filter pattern CFP2. That is, the second color filter pattern CFP2 may overlap the second sub-pixel area SPX2, and may not overlap the first color filter layer CF1 and the third color filter layer CF3.

The third color filter layer CF3 may overlap the third sub-pixel area SPX3 and the light-blocking area BA, and may not overlap the first sub-pixel area SPX1 and the second sub-pixel area SPX2. A portion of the third color filter layer CF3 that does not overlap with the first color filter layer CF1 and the second color filter layer CF2 may be defined as a third color filter pattern CFP3. That is, the third color filter pattern CFP3 may overlap the third sub-pixel area SPX3, and may not overlap the first color filter layer CF1 and the second color filter layer CF2.

In this case, a portion of the first color filter layer CF1, a portion of the second color filter layer CF2, and a portion of the third color filter layer CF3 excluding the first to third color filter patterns CFP1, CFP2, and CFP3 may respectively overlap each other in the third direction DR3 in the light-blocking area BA. Accordingly, the color filter layer CF may effectively block light traveling in the third direction DR3. Accordingly, color mixing between the first to third sub-pixel areas SPX1, SPX2, and SPX3 that are respectively adjacent may be prevented or reduced.

For example, in the light-blocking area BA, the third color filter layer CF3 may be under the first substrate SUB1, the first color filter layer CF1 may be under the third color filter layer CF3, and the second color filter layer CF2 may be under the first color filter layer CF1. However, in one or more embodiments, the arrangement order is not limited thereto.

External visual recognition (e.g., from outside of the display device 10) of a circuit structure, such as wirings and driving circuits located in the second area A2 of the color conversion substrate 100, may be reduced or prevented due to the color filter layer CF. In addition, a light leakage phenomenon, in which light reflected from the circuit structure or emitted from the first area A1 is then emitted through the second area A2 of the first substrate SUB1, may be prevented or reduced by the color filter layer CF.

In one or more embodiments, a low refractive index layer LR may be under the color filter layer CF, and may be on the color conversion layer CCL and the partition wall PT. The low refractive index layer LR may overlap the first area A1 and the second area A2, and may overlap the sealing member SLM. However, the present disclosure is not limited thereto.

The low refractive index layer LR may have a lower refractive index than the capping layer CP. The low refractive index layer LR may increase light extraction efficiency, and may increase luminance and lifetime of the display device 10. The low refractive index layer LR may include an organic material.

The capping layer CP may be under the low refractive index layer LR, and may be on the color conversion layer CCL and the partition wall PT. For example, the capping layer CP may cover the low refractive index layer LR.

In one or more embodiments, the capping layer CP may include an inorganic material. For example, the capping layer CP may include silicon oxynitride (SiOxNy).

The partition wall PT may be under the capping layer CP. The partition wall PT may include an opening OP. The opening OP of the partition wall PT may define the first sub-pixel area SPX1, the second sub-pixel area SPX2, and the third sub-pixel area SPX3. The partition wall PT may form/define the opening OP capable of accommodating an ink composition in a process of forming the color conversion layer CCL. For example, the partition wall PT may entirely overlap the light-blocking area BA. That is, an area overlapping the opening OP may be the sub-pixel area, and an area overlapping the partition wall PT may be the light-blocking area BA.

The partition wall PT may include an organic material. The partition wall PT may further include a light-blocking material. For example, at least a portion of the partition wall PT may include a light-blocking material, such as black pigment, dye, or carbon black.

In one or more embodiments, a width W of the partition wall PT located between the first sub-pixel area SPX1 and the second sub-pixel area SPX2 may be constant. Similarly, a width W of the partition wall PT located between the second sub-pixel area SPX2 and the third sub-pixel area SPX3 may be constant. Each of the width W of the partition wall PT between the first sub-pixel area SPX1 and the second sub-pixel area SPX2 and the width W of the partition wall PT between the second sub-pixel area SPX2 and the third sub-pixel area SPX3 may be about 5 micrometers to about 20 micrometers.

When each of the width W of the partition wall PT between the first sub-pixel area SPX1 and the second sub-pixel area SPX2, and the width W of the partition wall PT between the second sub-pixel area SPX2 and the third sub-pixel area SPX3, is less than about 5 micrometers, a distance between the first to third sub-pixel areas SPX1, SPX2, and SPX3 becomes relatively small, and color mixing may occur. That is, color mixing may easily occur between the first to third sub-pixel areas SPX1, SPX2, and SPX3 emitting light of different colors.

When each of the width W of the partition wall PT between the first sub-pixel area SPX1 and the second sub-pixel area SPX2, and the width W of the partition wall PT between the second sub-pixel area SPX2 and the third sub-pixel area SPX3, is greater than about 20 micrometers, an area of each of the first to third sub-pixel areas SPX1, SPX2, and SPX3 may be reduced. Accordingly, an opening ratio of each of the first to third sub-pixel areas SPX1, SPX2, and SPX3 may decrease, and thus light-emitting efficiency of the display device 10 may decrease.

The color conversion layer CCL may be in the opening OP of the partition wall PT. The color conversion layer CCL may be under the capping layer CP, and may overlap the first to third sub-pixel areas SPX1, SPX2, and SPX3. In one or more embodiments, the color conversion layer CCL may be formed by an inkjet process.

The color conversion layer CCL may include color conversion patterns spaced apart from each other on the lower surface of the capping layer CP. In one or more embodiments, the color conversion layer CCL may include a first color conversion pattern CCL1, a second color conversion pattern CCL2, and a transmission pattern TL. The first color conversion pattern CCL1, the second color conversion pattern CCL2, and the transmission pattern TL may be in the first area A1 under the color filter layer CF. The first color conversion pattern CCL1 may overlap the first sub-pixel area SPX1. The second color conversion pattern CCL2 may overlap the second sub-pixel area SPX2. The transmission pattern TL may overlap the third sub-pixel area SPX3. The first color conversion pattern CCL1, the second color conversion pattern CCL2, and the transmission pattern TL may be respectively located in the opening(s) OP of the partition wall PT.

The first color conversion pattern CCL1 may overlap the first sub-pixel area SPX1. The first color conversion pattern CCL1 may convert incident light (e.g., incident light L1 of FIG. 7) emitted from the array substrate 200 into a first light having a red color. For example, the first color conversion pattern CCL1 may include a resin part CCL1a, a scattering material CCL1b, and a wavelength conversion particle CCL1c.

The scattering material CCL1b may increase an optical path by scattering the incident light without substantially changing a wavelength of the incident light incident on the first color conversion pattern CCL1. The scattering material CCL1b may include a metal oxide or an organic material. Optionally, the scattering material CCL1b may be omitted.

In one or more embodiments, the wavelength conversion particle CCL1c may include a quantum dot. The quantum dot may be defined as a semiconductor material having nanocrystals. The quantum dot may have a corresponding band gap depending on its composition and size. Accordingly, the quantum dot may absorb the incident light L1, and may emit light having a different wavelength from that of the incident light. For example, the quantum dot may have a diameter of about 100 nm or less, for example about 1 nm to about 20 nm. For example, the wavelength conversion particles CCL1c of the first color conversion pattern CCL1 may include a quantum dot that absorbs the incident light, and may emit red light.

The scattering material CCL1b and the wavelength conversion particle CCL1c may be in the resin part CCL1a. For example, the resin part CCL1a may include an epoxy-based resin, an acrylic-based resin, a phenol-based resin, a melamine-based resin, a cardo-based resin, an imide-based resin, or the like.

The second color conversion pattern CCL2 may overlap the second sub-pixel area SPX2. The second color conversion pattern CCL2 may convert the incident light into second light having a green color. For example, the second color conversion pattern CCL2 may include the resin part CCL2a, the scattering material CCL2b, and the wavelength conversion particle CCL2c. The resin part CCL2a and the scattering material CCL2b of the second color conversion pattern CCL2 may be substantially the same as, or similar to, the resin part CCL1a and the scattering material CCL1b of the first color conversion pattern CCL1.

For example, the wavelength conversion particles CCL2c of the second color conversion pattern CCL2 may include a quantum dot that absorbs the incident light, and may emit green light. Accordingly, the second color conversion pattern CCL2 may emit the second light having green color by converting the incident light.

The transmission pattern TL may overlap the third sub-pixel area SPX3. The transmission pattern TL may emit third light by transmitting the incident light. For example, the transmission pattern TL may include the resin part TLa and the scattering material TLb. The resin part TLa and the scattering material TLb of the transmission pattern TL may be substantially the same as, or similar to, the resin part CCL1a and the scattering material CCL1b of the first color conversion pattern CCL1.

However, the present disclosure is not limited thereto, and the transmission pattern TL may convert the incident light into the third light having a blue color. In this case, the transmission pattern TL may further include a wavelength conversion particle including a quantum dot that absorb the incident light, and may emit blue light.

The protective layer PL may be under the color conversion layer CCL and the partition wall PT. The protective layer PL may protect the color conversion layer CCL from oxygen, moisture, foreign matter, or the like. The protective layer PL may cover the partition wall PT and the color conversion layer CCL.

In one or more embodiments, the protective layer PL may include an inorganic material. For example, the protective layer PL may include silicon oxide (SiOx), silicon nitride (SiNx), silicon oxynitride (SiOxNy), or the like. These materials may be used alone or in combination.

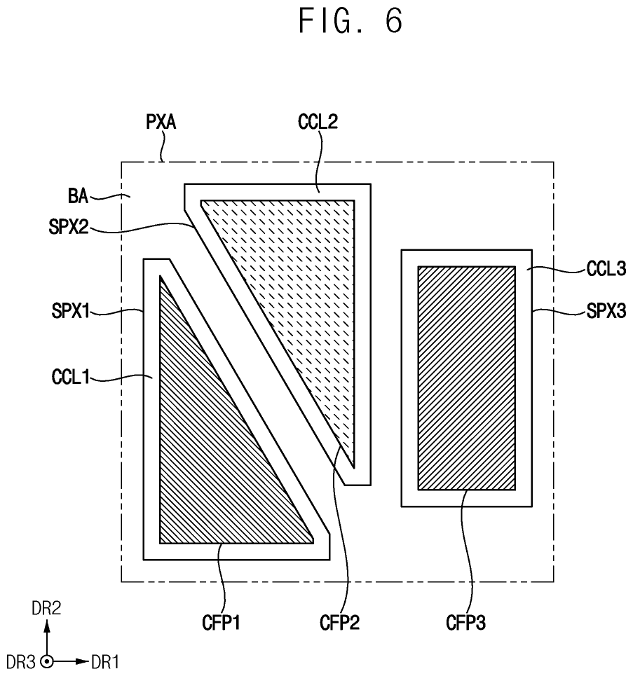

FIG. 6 is a plan view illustrating only the color conversion layer and the color filter layer of FIG. 5.

For example, in FIG. 6, only the first color filter pattern CFP1, the second color filter pattern CFP2, and the third color filter pattern CFP3 of the color filter layer CF of FIG. 5 are illustrated.

Referring further to FIG. 6, the first color conversion pattern CCL1 may be in the first sub-pixel area SPX1, and the area of the first sub-pixel area SPX1 and an area of the first color conversion pattern CCL1 may be substantially equal. The second color conversion pattern CCL2 may be in the second sub-pixel area SPX2, and the area of the second sub-pixel area SPX2 and an area of the second color conversion pattern CCL2 may be substantially equal. The transmission pattern TL may be in the third sub-pixel area SPX3, and the area of the third sub-pixel area SPX3 and the transmission pattern TL may be substantially equal.

In one or more embodiments, the first color filter pattern CFP1 may be in the first sub-pixel area SPX1, and an area of the first color filter pattern CFP1 may be less than the area of the first sub-pixel area SPX1. The second color filter pattern CFP2 may be in the second sub-pixel area SPX2, and an area of the second color filter pattern CFP2 may be less than the area of the second sub-pixel area SPX2. The third color filter pattern CFP3 may be in the third sub-pixel area SPX3, and an area of the third color filter pattern CFP3 may be less than the area of the third sub-pixel area SPX3. That is, the first to third color filter patterns CFP1, CFP2, and CFP3 may have shapes that are similar to shapes of the first to third sub-pixel areas SPX1, SPX2, and SPX3, respectively. Although each of the first color filter patterns CFP1 and the second color filter pattern CFP2 is illustrated as a right-angled triangle shape in FIG. 6, the present disclosure is not limited thereto. For example, each of the first color filter patterns CFP1 and the second color filter pattern CFP2 may have a chamfered right-angled triangle shape.

In one or more embodiments, the area of the first color filter pattern CFP1 may be greater than the area of the second color filter pattern CFP2, and the area of the second color filter pattern CFP2 may be greater than the area of the third color filter pattern CFP3

FIG. 7 is an enlarged cross-sectional view of a portion of the display device of FIG. 2.

Referring to FIGS. 1 to 7, the display device 10 may include the color conversion substrate 100 and the array substrate 200. Light L1 (hereinafter, referred to as incident light) generated from the array substrate 200 and incident to the color conversion substrate 100 may be emitted to outside through the sub-pixel area.

The color conversion substrate 100 may include the first substrate SUB1, the color filter layer CF, the partition wall PT, the color conversion layer CCL, the low refractive index layer LR, the capping layer CP, and the protective layer PL.

The array substrate 200 may include a second substrate SUB2, a buffer layer BFR, a plurality of driving elements, an insulating layer IL, a pixel-defining layer PDL, a plurality of light-emitting diodes, and an encapsulation layer ECL.

The second substrate SUB2 may face, or may be opposite to, the first substrate SUB1. The second substrate SUB2 may include the first area A1 and the second area A2 as the display device 10 includes the first area A1 and the second area A2 described above.

The second substrate SUB2 may be an insulating substrate formed of a transparent or opaque material. In one or more embodiments, the second substrate SUB2 may include glass. In this case, the array substrate 200 may be a rigid display substrate. In one or more other embodiments, the second substrate SUB2 may include plastic. In this case, the array substrate 200 may be a flexible display substrate.

The buffer layer BFR may be on the second substrate SUB2. The buffer layer BFR may reduce or prevent impurities, such as oxygen and moisture from diffusing onto the second substrate SUB2 through the second substrate SUB2. The buffer layer BFR may include an inorganic material, such as a silicon compound or a metal oxide. The buffer layer BFR may have a single-layer structure or a multi-layer structure including a plurality of insulating layers.

The plurality of driving elements may include the first to third driving elements TR1, TR2, and TR3. The first to third driving elements TR1, TR2, and TR3 may be in the first area A1 on the buffer layer BFR. Each of the first to third driving elements TR1, TR2, and TR3 may include at least one thin film transistor. A channel layer of the thin film transistor may include an oxide semiconductor, a silicon semiconductor, or an organic semiconductor. For example, the oxide semiconductor may include at least one oxide of indium (In), gallium (Ga), tin (Sn), zirconium (Zr), vanadium (V), hafnium (Hf), cadmium (Cd), germanium (Ge), chromium It may (Cr), titanium (Ti), and/or zinc (Zn). The silicon semiconductor may include amorphous silicon, polycrystalline silicon, or the like.

The insulating layer IL may cover the first to third driving elements TR1, TR2, and TR3. The insulating layer IL may include a combination of an inorganic insulating layer and an organic insulating layer.

The plurality of light-emitting diodes may be on the insulating layer IL. The plurality of light-emitting diodes may include the first to third light-emitting diodes LED1, LED2, and LED3. The first light-emitting diode LED1 may overlap the first sub-pixel area SPX1, the second light-emitting diode LED2 may overlap the second sub-pixel area SPX2, and the third light-emitting diode LED3 may overlap the third sub-pixel area SPX3.

For example, first to third pixel electrodes AE1, AE2, and AE3 may be on the insulating layer IL. The first pixel electrode AE1 may overlap the first sub-pixel area SPX1, the second pixel electrode AE2 may overlap the second sub-pixel area SPX2, and the third pixel electrode AE3 may overlap the third sub-pixel area SPX3.

Each of the first to third pixel electrodes AE1, AE2, and AE3 may include a conductive material, such as a metal, an alloy, a conductive metal nitride, a conductive metal oxide, or a transparent conductive material. Each of the first to third pixel electrodes AE1, AE2, and AE3 may have a single-layer structure or a multi-layer structure including a plurality of conductive layers.

The first to third pixel electrodes AE1, AE2, and AE3 may be electrically connected to the first to third driving elements TR1, TR2, and TR3 through contact holes formed in the insulating layer IL, respectively.

The pixel-defining layer PDL may be on the first to third pixel electrodes AE1, AE2, and AE3. The pixel-defining layer PDL may include an organic material. The pixel-defining layer PDL may define a pixel opening for exposing at least a portion of each of the first to third pixel electrodes AE1, AE2, and AE3.

The light-emitting layer EL may be on the first to third pixel electrodes AE1, AE2, and AE3 exposed by the pixel opening of the pixel-defining layer PDL. In one or more embodiments, the light-emitting layer EL may continuously extend on the first area A1 over a plurality of pixels. In one or more other embodiments, the light-emitting layer EL may be separated from the light-emitting layer of an adjacent pixel.

The light-emitting layer EL may include at least one of an organic light-emitting material and/or quantum dots. In one or more embodiments, the light-emitting layer EL may generate blue light. However, the present disclosure is not limited thereto. In one or more other embodiments, the light-emitting layer EL may generate red light or green light, or may generate lights having different colors according to pixels.

For example, all of the light-emitting layers EL may include an organic material for emitting blue light. In this case, the light-emitting layer EL may be formed in multiple layers, and may have a structure in which a plurality of blue organic light-emitting layers are stacked. For example, the light-emitting layer EL may have a structure in which three blue organic light-emitting layers are stacked.

However, the present disclosure is not limited thereto, and the light-emitting layer EL may have a structure in which a plurality of blue organic light-emitting layers and an organic light-emitting layer for emitting light of different colors are stacked. For example, the light-emitting layer EL may have a structure in which three blue organic light-emitting layers and one green organic light-emitting layer are stacked. In one or more embodiments, functional layers, such as a hole injection layer, a hole transport layer, an electron transport layer, and/or an electron injection layer, may be above and/or below the light-emitting layer EL.

A common electrode CE may be on the light-emitting layer EL. The common electrode CE may include a conductive material, such as a metal, an alloy, a conductive metal nitride, a conductive metal oxide, or a transparent conductive material. The common electrode CE may have a single-layer structure or a multi-layer structure including a plurality of conductive layers. In one or more embodiments, the common electrode CE may continuously extend on the first area A1 over a plurality of pixels.

The first light-emitting diode LED1 may include the first pixel electrode AE1, the light-emitting layer EL, and the common electrode CE, the second light-emitting diode LED2 may include the second pixel electrode AE2, the light-emitting layer EL, and the common electrode CE, and the third light-emitting diode LED3 may include the third pixel electrode AE3, the light-emitting layer EL, and the common electrode CE. The light-emitting diodes LED1, LED2, and LED3 may overlap the first to third sub-pixel regions SPX1, SPX2, and SPX3 defined by the opening(s) OP, respectively. Accordingly, the color conversion layer CCL may be on the light-emitting diodes LED1, LED2, and LED3.

In one or more embodiments, the first color conversion pattern CCL1 may overlap the first sub-pixel area SPX1. The first color conversion pattern CCL1 may convert the incident light L1 into the first light L2R having a red color.

The incident light L1 that is not converted by the first color conversion pattern CCL1 may be blocked by the first color filter layer CF1. Accordingly, in the first sub-pixel area SPX1, the first light L2R having red color may be emitted to outside (e.g., in the third direction DR3) by passing through the first substrate SUB1.

In one or more embodiments, the second color conversion pattern CCL2 may overlap the second sub-pixel area SPX2. The second color conversion pattern CCL2 may convert the incident light L1 into the second light L2G having a green color.

The incident light L1 not converted by the second color conversion pattern CCL2 may be blocked by the second color filter pattern CF2. Accordingly, in the second sub-pixel area SPX2, the second light L2G having green color may be emitted to outside (e.g., in the third direction DR3) by passing through the first substrate SUB1.

In one or more embodiments, the transmission pattern TL may overlap the third sub-pixel area SPX3. The transmission pattern TL may transmit the incident light L1 to emit the third light L2B.

Some of the incident light L1 may be blocked by the third color filter layer CF3. Accordingly, in the third sub-pixel area SPX3, the third light L2B having a blue color is emitted to outside (e.g., in the third direction DR3) by passing through the first substrate SUB1.

The image may be displayed in the first area A1 as the first to third lights L2R, L2G, and L2B emitted to outside through the first substrate SUB1 are combined in the first to third sub-pixel areas SPX1, SPX2, and SPX3.

The encapsulation layer ECL may be on the common electrode CE. The encapsulation layer ECL may include at least one inorganic encapsulation layer and at least one organic encapsulation layer. In one or more embodiments, the encapsulation layer ECL may include a first inorganic encapsulation layer IEL1 located on the common electrode CE, an organic encapsulation layer OEL located on the first inorganic encapsulation layer IEL1, and a second inorganic encapsulation layer IEL2 located on the organic encapsulation layer OEL.

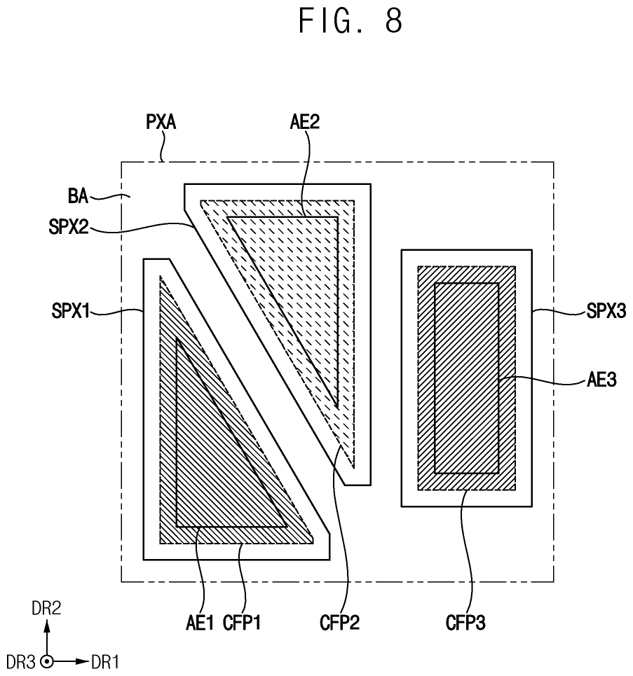

FIG. 8 is a plan view illustrating only the color conversion layer, color filter layer, and pixel electrodes of FIG. 7.

For example, in FIG. 8, only the first color filter pattern CFP1, the second color filter pattern CFP2, and the third color filter pattern CFP3 of the color filter layer CF of FIG. 7 may be illustrated.

Referring to FIGS. 6 to 8, the first color filter pattern CFP1 and the first pixel electrode AE1 may be in the first sub-pixel area SPX1. The second color filter pattern CFP2 and the second pixel electrode AE2 may be in the second sub-pixel area SPX2. The third color filter pattern CFP3 and the third pixel electrode AE3 may be in the third sub-pixel area SPX3.

In one or more embodiments, an area of the first pixel electrode AE1 may be less than the area of the first sub-pixel area SPX1 and the area of the first color filter pattern CFP1. An area of the second pixel electrode AE2 may be less than the area of the second sub-pixel area SPX2 and the area of the second color filter pattern CFP2. An area of the third pixel electrode AE3 may be less than the area of the third sub-pixel area SPX3 and the area of the third color filter pattern CFP3. That is, the first to third pixel electrodes AE1, AE2, and AE3 may have shapes similar to shapes of the first to third sub-pixel areas SPX1, SPX2, and SPX3, respectively. Although each of the first pixel electrode AE1 and the second pixel electrode AE2 is illustrated as a right-angled triangle shape in FIG. 8, the present disclosure is not limited thereto. For example, each of the first pixel electrode AE1 and the second pixel electrode AE2 may have a chamfered right-angled triangle shape.

In one or more embodiments, as the color conversion substrate 100 includes the first to third sub-pixel areas SPX1, SPX2, and SPX3 overlapping each other in the first direction DR1, an overlapping area of the three sub-pixel areas SPX1, SPX2, and SPX3 in the first direction DR1 may increase. Accordingly, a color phenomenon in which upper and lower edges in the pixel area (e.g., the pixel area PXA of FIG. 3) are displayed in green or magenta instead of white may be improved. In addition, as each of the first sub-pixel area SPX1 and the second sub-pixel area SPX2 have a shape in which a width becomes narrower or wider toward the second direction DR2, luminous efficiency of the display device 10 may be increased.

In addition, because the third sub-pixel area SPX3 has a rectangular shape, it is possible to easily correct misplaced shots. As a result, efficiency in the manufacturing process of the display device 10 may be improved.

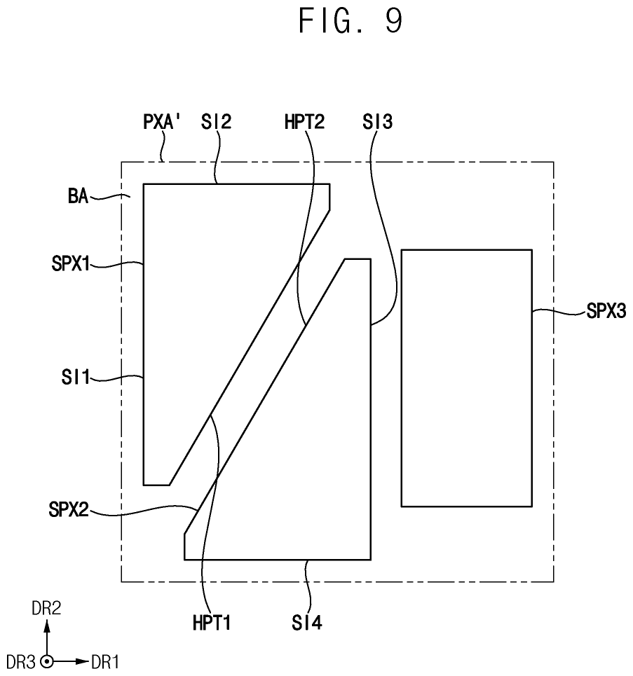

FIG. 9 is a plan view illustrating another example of FIG. 4.

The pixel area PXA′ described with reference to FIG. 9 may be substantially the same as the pixel area PXA described with reference to FIG. 4 except for the first sub-pixel area SPX1 and the second sub-pixel area SPX2. Accordingly, redundant descriptions will be omitted or simplified.

Referring to FIG. 9, the pixel area PXA′ may include a sub-pixel area and a light-blocking area BA. For example, the pixel area PXA′ may include a first sub-pixel area SPX1, a second sub-pixel area SPX2, a third sub-pixel area SPX3, and a light-blocking area BA. The first sub-pixel area SPX1, the second sub-pixel area SPX2, and the third sub-pixel area SPX3 may emit light of different colors.

In one or more embodiments, the first sub-pixel area SPX1, the second sub-pixel area SPX2, and the third sub-pixel area SPX3 may be sequentially arranged in the first direction DR1. Also, the first sub-pixel area SPX1, the second sub-pixel area SPX2, and the third sub-pixel area SPX3 may overlap each other in the first direction DR1.

In one or more embodiments, the first sub-pixel area SPX1 may have a right-angled triangle shape in which at least one of the corners, other than a corner forming the right angle, is chamfered. Accordingly, the first sub-pixel area SPX1 may include a first hypotenuse HPT1. Also, similarly, the second sub-pixel area SPX2 may have a right-angled triangle shape in which at least one of corners, other than a corner forming a right angle, is chamfered. The second sub-pixel area SPX2 may include a second hypotenuse HPT2.

In one or more embodiments, the first hypotenuse HPT1 of the first sub-pixel area SPX1 and the second hypotenuse HPT2 of the second sub-pixel area SPX2 may be adjacent to each other. The first hypotenuse HPT1 and the second hypotenuse HPT2 may be entirely spaced apart from each other by a distance (e.g., predetermined distance).

Also, the first sub-pixel area SPX1 may include a first side SI1 and a second side SI2 that are substantially perpendicular to each other. A length of the first side SI1 may be greater than or equal to a length of the second side SI2. Similarly, the second sub-pixel area SPX2 may include a third side SI3 and a fourth side SI4 that are substantially perpendicular to each other. A length of the third side SI3 may be greater than or equal to a length of the fourth side SI4.

However, the present disclosure is not limited thereto, and in one or more other embodiments, the first side SI1 and the second side SI2 of the first sub-pixel area SPX1 may form an obtuse angle or an acute angle rather than a right angle to each other, and the third side SI3 and the fourth side SI4 of the second sub-pixel area SPX2 may form an obtuse angle or an acute angle rather than a right angle to each other.

In one or more embodiments, the first side SI1 and the third side SI3 may be substantially parallel to each other. The second side SI2 and the fourth side SI4 may be substantially parallel to each other.

In one or more embodiments, an area obtained by combining the first sub-pixel area SPX1 and the second sub-pixel area SPX2 may have a shape that is similar to a rectangular shape as a whole. In this case, the rectangular shape may be divided by an oblique line crossing the rectangular shape to define a shape of the first sub-pixel area SPX1 and a shape of the second sub-pixel area SPX2.

In one or more embodiments, the first sub-pixel area SPX1 may have a shape in which a width becomes wider toward the second direction DR2. Unlike this, the second sub-pixel area SPX2 may have a shape in which a width becomes narrower toward the second direction DR2.

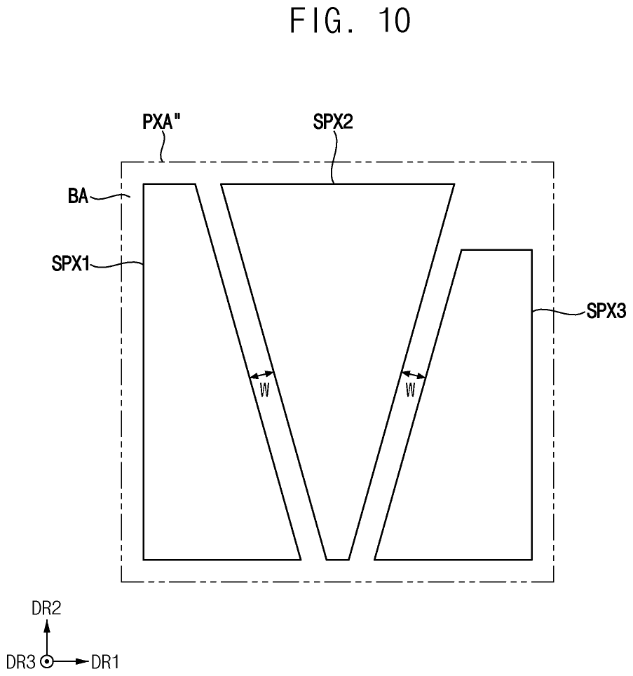

In one or more embodiments, the second side SI2 may be spaced apart from the third side SI3 in the second direction DR2. Also, the fourth side SI4 may be spaced apart from the first side SI1 in a direction opposite to the second direction DR2. FIG. 10 is a plan view illustrating still another example of FIG. 4.

The pixel area PXA″ described with reference to FIG. 10 may be substantially the same as the pixel area PXA described with reference to FIG. 4, except for a shape of the first pixel area SPX1, a shape of the second pixel area SPX2, and a shape of the third sub-pixel area SPX3. Accordingly, redundant descriptions will be omitted or simplified.

The first sub-pixel area SPX1, the second sub-pixel area SPX2, and the third sub-pixel area SPX3 may be spaced apart from each other in a plan view. In addition, as the pixel areas PXA are repeatedly aligned with each other, the first sub-pixel area SPX1, the second sub-pixel area SPX2, and the third sub-pixel area SPX3 may also be arranged to be repeated each other.

In one or more embodiments, the first sub-pixel area SPX1, the second sub-pixel area SPX2, and the third sub-pixel area SPX3 may be sequentially arranged in the first direction DR1. Also, the first sub-pixel area SPX1, the second sub-pixel area SPX2, and the third sub-pixel area SPX3 may overlap each other in the first direction DR1. In one or more embodiments, the first sub-pixel area SPX1, the second sub-pixel area SPX2, and the third sub-pixel area SPX3 may entirely overlap each other in the first direction DR1.

In one or more embodiments, the first sub-pixel area SPX1 may have a trapezoidal shape. For example, the first sub-pixel area SPX1 may have a trapezoidal shape including a right-angled corner. Similarly, the third sub-pixel area SPX3 may have a trapezoidal shape. For example, the third sub-pixel area SPX3 may have a trapezoidal shape including a right-angled corner. However, the present disclosure is not limited thereto, and in one or more other embodiments, each of the first sub-pixel area SPX1 and the third sub-pixel area SPX3 may have a trapezoidal shape including an obtuse corner or an acute angle corner, rather than a right-angled corner.

In one or more embodiments, the second sub-pixel area SPX2 may have a trapezoidal shape. Also, the second sub-pixel area SPX2 may be entirely spaced apart from each of the first sub-pixel area SPX1 and the third sub-pixel area SPX3 by a distance (e.g., predetermined distance) W. That is, each of a width W of the partition wall PT between the first sub-pixel area SPX1 and the second sub-pixel area SPX2, and a width W of the partition wall PT between the second sub-pixel area SPX2 and the third sub-pixel area SPX3, may be constant. For example, the second sub-pixel area SPX2 may be spaced apart from each of the first sub-pixel area SPX1 and the third sub-pixel area SPX3 by about 5 micrometers to about 20 micrometers. Accordingly, light-emitting efficiency of the display device 10 may be increased without color mixing between the first to third sub-pixel areas SPX1, SPX2, and SPX3.

In one or more embodiments, a longest side of the first sub-pixel area SPX1 may be adjacent to the second sub-pixel area SPX2. Similarly, a longest side of the third sub-pixel area SPX3 may be adjacent to the second sub-pixel area SPX2.

In one or more embodiments, each of the first sub-pixel area SPX1 and the third sub-pixel area SPX3 may have a shape in which a width becomes narrower toward the second direction DR2. Contrastingly, the second sub-pixel area SPX2 may have a shape in which a width becomes wider toward the second direction DR2. Therefore, because the first to third sub-pixel areas SPX1, SPX2, and SPX3 are alternately located, an opening ratio of each of the first to third sub-pixel areas SPX3 in the pixel area PXA may be increased.

In one or more embodiments, an area obtained by combining the first sub-pixel area SPX1, the second sub-pixel area SPX2, and the third sub-pixel area SPX3 may have a shape that is similar to a square shape as a whole. In this case, the square shape may be divided by two oblique lines crossing the square shape to define a shape of the first sub-pixel area SPX1, a shape of the second sub-pixel area SPX2, and a shape of the third sub-pixel area.

In one or more embodiments, a length of the first sub-pixel area SPX1 in the second direction DR2, and a length of the second sub-pixel area SPX2 in the second direction DR2, may be substantially equal. A length of the third sub-pixel area SPX3 in the second direction DR2 may be less than each of the length of the first sub-pixel area SPX1 in the second direction DR2 and the length of the second sub-pixel area SPX2 in the second direction DR2. Accordingly, a spacer for maintaining a gap may be in an area of the pixel area PXA where the first to third sub-pixel areas SPX1, SPX2, and SPX3 are not located. However, the present disclosure is not limited thereto.

In one or more embodiments, an area of the first sub-pixel area SPX1 may be greater than or equal to an area of the second sub-pixel area SPX2. Also, the area of the second sub-pixel area SPX2 may be greater than an area of the third sub-pixel area SPX3.

In one or more embodiments, as wide portions of each of the first to third sub-pixel areas SPX1, SPX2, and SPX3 are alternately located, an area of the first to third sub-pixel areas SPX1, SPX2, SPX3 in the pixel area PXA may be increased. Accordingly, an opening ratio of each of the first to third sub-pixel areas SPX3 may be increased, and light-emitting efficiency of the display device 10 may be improved.

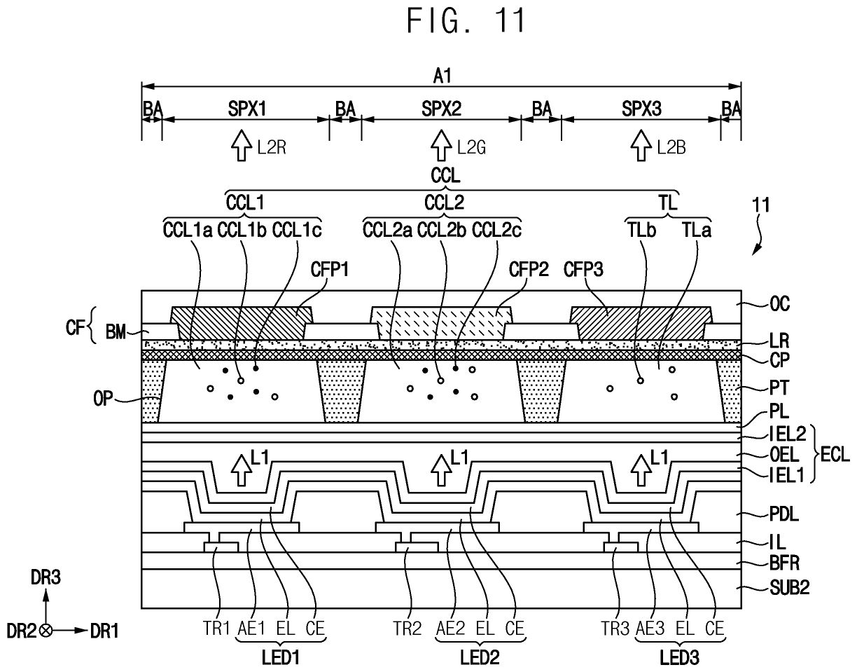

FIG. 11 is a cross-sectional view illustrating another example of FIG. 7.

For example, among descriptions of a display device 11 with reference to FIG. 11, descriptions overlapping with the display device 10 of FIG. 7 may be omitted or simplified.

Referring to FIG. 11, the display device 11 may include a second substrate SUB2, a buffer layer BFR, a plurality of driving elements TR1, TR2, and TR3, an insulating layer IL, a pixel-defining layer PDL, a plurality of light-emitting diodes LED1, LED2, and LED3, an encapsulation layer ECL, a protective layer PL, a partition wall PT, a color conversion layer CCL, a capping layer CP, a low refractive index layer LR, a black matrix BM, a color filter layer CF, and a planarization layer OC.

The second substrate SUB2 may include a plurality of pixel areas PXA. Each of the plurality of pixel areas PXA may include a first sub-pixel area SPX1, a second sub-pixel area SPX2, and a third sub-pixel area SPX3.

The second substrate SUB2 may be an insulating substrate formed of a transparent material. The second substrate SUB2 may include glass or plastic.

The buffer layer BFR may be on the second substrate SUB2. The driving elements TR1, TR2, and TR3 and the insulating layer IL may be on the buffer layer BFR. The light-emitting diodes LED1, LED2, and LED3 and the pixel-defining layer PDL may be on the insulating layer IL. The encapsulation layer ECL may be on the light-emitting diodes LED1, LED2, and LED3.

The protective layer PL may be on the encapsulation layer ECL. The protective layer PL may protect the color conversion layer CCL from oxygen, moisture, foreign matter, or the like.

The partition wall PT may be on the protective layer PL. The partition wall PT may include an opening OP. The opening OP of the partition wall PT may define the first sub-pixel area SPX1, the second sub-pixel area SPX2, and the third sub-pixel area SPX3. For example, the partition wall PT may entirely overlap a light-blocking area BA. That is, an area overlapping the opening OP may be the sub-pixel area, and an area overlapping the partition wall PT may be the light-blocking area BA.

The partition wall PT may include an organic material. The partition wall PT may further include a light-blocking material. For example, at least a portion of the partition wall PT may include a light-blocking material, such as black pigment, dye, or carbon black.

The color conversion layer CCL may be in the opening OP of the partition wall PT. The color conversion layer CCL may be on the protective layer PL and may overlap the first to third sub-pixel areas SPX1, SPX2, and SPX3. In one or more embodiments, the color conversion layer CCL may be formed by an inkjet process.

The color conversion layer CCL may include a first color conversion pattern CCL1, a second color conversion pattern CCL2, and a transmission pattern TL. The first color conversion pattern CCL1, the second color conversion pattern CCL2, and the transmission pattern TL may be in the first area A1 under the color filter layer CF. The first color conversion pattern CCL1 may overlap the first sub-pixel area SPX1. The second color conversion pattern CCL2 may overlap the second sub-pixel area SPX2. The transmission pattern TL may overlap the third sub-pixel area SPX3. The first color conversion pattern CCL1, the second color conversion pattern CCL2, and the transmission pattern TL may be respectively located in the opening OP of the partition wall PT.

The first color conversion pattern CCL1 may overlap the first sub-pixel area SPX1. The first color conversion pattern CCL1 may convert an incident light L1 into a first light L2R having a red color. The second color conversion pattern CCL2 may overlap the second sub-pixel area SPX2. The second color conversion pattern CCL2 may convert the incident light L1 into a second light L2G having a green color. The transmission pattern TL may overlap the third sub-pixel area SPX3. The transmission pattern TL may transmit the incident light L1 to emit a third light L2B.

The capping layer CP may be on the color conversion layer CCL and the partition wall PT, and may be under the low refractive index layer LR. The capping layer CP may include an inorganic material.

The low refractive index layer LR may be on the capping layer CP, and may be under the color filter layer CF and the black matrix BM. The low refractive index layer LR may improve light extraction efficiency, and thus may increase luminance and lifetime of the display device 11. The low refractive index layer LR may include an organic material.

The black matrix BM may be on the low refractive index layer LR. The black matrix BM may overlap the light-blocking area BA. The black matrix BM may be formed of a light-blocking material, and may block light emitted from a lower portion. Accordingly, the black matrix BM may effectively block light traveling in the third direction DR3. Accordingly, color mixing between the first to third sub-pixel areas SPX1, SPX2, and SPX3 that are adjacent may be prevented or reduced. Also, the black matrix BM may define an opening in which the color filter layer CF is located. The opening may overlap each of the first to third sub-pixel areas SPX1, SPX2, and SPX3.

The color filter layer CF may be on the low refractive index layer LR. The color filter layer CF may include a first color filter pattern CFP1, a second color filter pattern CFP2, and a third color filter pattern CFP3. The first to third color filter patterns CFP1, CFP2, and CFP3 may be respectively located in the opening of the black matrix BM.

The first color filter pattern CFP1 may overlap the first sub-pixel area SPX1, and may selectively transmit a red light. The second color filter pattern CFP2 may overlap the second sub-pixel area SPX2, and may selectively transmit a green light. The third color filter pattern CFP3 may overlap the third sub-pixel area SPX3, and may selectively transmit a blue light.

The planarization layer OC may be on the color filter layer CF and the black matrix BM. That is, the planarization layer OC may cover the color filter layer CF and the black matrix BM. The planarization layer OC may be formed of an organic material, and may provide a substantially flat upper surface.

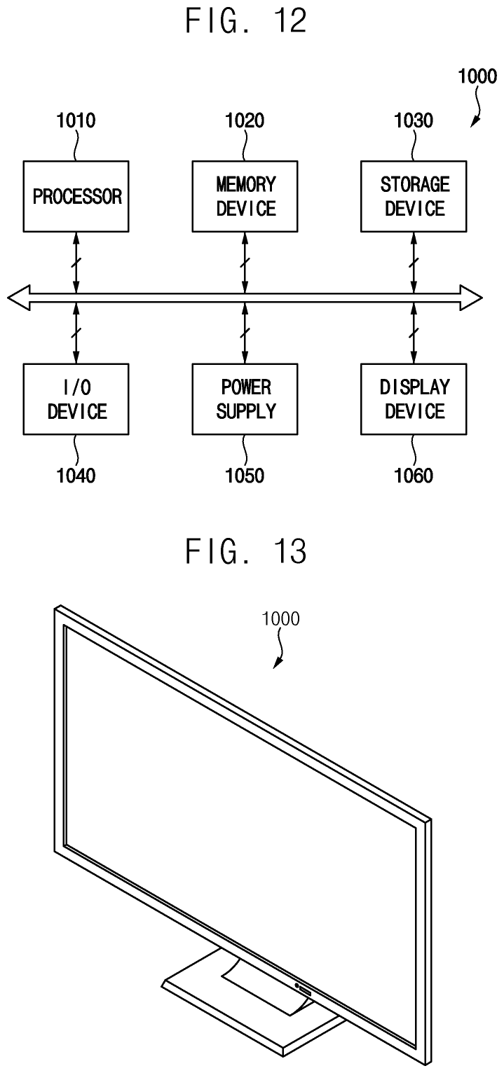

FIG. 12 is a block diagram illustrating an electronic device according to embodiments, and FIG. 13 is a diagram illustrating a case in which the electronic device of FIG. 12 is implemented as a monitor.

Referring to FIGS. 12 and 13, an electronic device 1000 may include a processor 1010, a memory device 1020, a storage device 1030, an input/output device 1040, a power supply 1050, and a display device 1060. In this case, the display device 1060 may be the display device of FIG. 1. In addition, the electronic device 1000 may further include several ports capable of communicating with a video card, sound card, memory card, USB device, etc., or with other systems. In one or more embodiments, as shown in FIG. 13, the electronic device 1000 may be implemented as a monitor. However, this is only an example, and the electronic device 1000 is not limited thereto. For example, the electronic device 1000 may be implemented as a mobile phone, a smart phone, a video phone, a smart pad, a smart watch, a tablet PC, a vehicle navigation device, a computer monitor, a television, a laptop computer, a head mounted display device, or the like.

The processor 1010 may perform certain calculations or tasks. Depending on the embodiment, the processor 1010 may be a microprocessor, a central processing part, an application processor, or the like. The processor 1010 may be connected to other components through an address bus, a control bus, and a data bus. According to one or more embodiments, the processor 1010 may be connected to an expansion bus, such as a Peripheral Component Interconnect (PCI) bus.

The memory device 1020 may store data suitable for the operation of the electronic device 1000. For example, the memory device 1020 may include an Erasable Programmable Read-Only Memory (EPROM) device, an Electrically Erasable Programmable Read-Only Memory (EEPROM) device, a flash memory device, and a PRAM. (Phase Change Random Access Memory; PRAM) device, Resistance Random Access Memory (RRAM) device, Nano Floating Gate Memory (NFGM) device, Polymer Random Access Memory (PoRAM) device, MRAM (Magnetic Non-volatile memory devices, such as Random Access Memory (MRAM), Ferroelectric Random Access Memory (FRAM) devices, and/or Dynamic Random Access Memory (DRAM) devices, Static Random Access Memory (SRAM) devices, a volatile memory device, such as a mobile DRAM device, or the like.

The storage device 1030 may include a solid state drive (SSD), a hard disk drive (HDD), a CD-ROM, or the like.

The input/output device 1040 may include an input means, such as a keyboard, a keypad, a touch pad, a touch screen, and a mouse, and an output means, such as a speaker and a printer. Depending on embodiments, the display device 1060 may be included in the input/output device 1040.

The power supply 1050 may supply power suitable for operation of the electronic device 1000. For example, the power supply 1050 may be a power management integrated circuit (PMIC).

The display device 1060 may display an image corresponding to visual information of the electronic device 1000. In this case, the display device 1060 may be an organic light-emitting display device or a quantum dot light-emitting display device, but is not limited thereto. The display device 1060 may be connected to other components through the buses or other communication links. In this case, because the display device 1060 includes the first to third sub-pixel areas overlapping each other in a first direction, in the display device 1060, a color phenomenon in which upper and lower edges in the pixel area are displayed in green or magenta instead of white may be improved. Further, because each of the first sub-pixel area and the second sub-pixel area has a shape in which a width becomes narrower or wider toward the second direction, luminous efficiency of the display device may be increased.

The present disclosure should not be construed as being limited to the embodiments set forth herein. Rather, these embodiments are provided so that this disclosure will be thorough and complete and will fully convey the concept of the claimed embodiments to those skilled in the art.

While the disclosure has been particularly shown and described with reference to embodiments thereof, it will be understood by those of ordinary skill in the art that various changes in form and details may be made therein without departing from the spirit or scope of the present disclosure as defined by the following claims, with functional equivalents thereof to be included therein.

What is claimed is:

1. A color conversion substrate comprising:
a substrate comprising a first sub-pixel area, a second sub-pixel area, and a third sub-pixel area configured to emit light of different respective colors, and spaced apart from each other in a first direction,
wherein each of the first sub-pixel area and the second sub-pixel area has a right-angled triangle shape in which at least one of corners other than a corner forming a right angle is chamfered, and
wherein the third sub-pixel area has a quadrilateral shape.

2. The color conversion substrate of claim 1, wherein the first sub-pixel area, the second sub-pixel area, and the third sub-pixel area overlap each other in the first direction.

3. The color conversion substrate of claim 1, wherein a hypotenuse of the first sub-pixel area and a hypotenuse of the second sub-pixel area are adjacent to each other.

4. The color conversion substrate of claim 1, wherein the first sub-pixel area comprises a first side and a second side that are substantially perpendicular to each other, a length of the first side being greater than or equal to a length of the second side, and
wherein the second sub-pixel area comprises a third side and a fourth side that are substantially perpendicular to each other, a length of the third side being greater than or equal to a length of the fourth side.

5. The color conversion substrate of claim 4, wherein the first side and the third side are substantially parallel to each other, and
wherein the second side and the fourth side are substantially parallel to each other.

6. The color conversion substrate of claim 4, wherein the fourth side is spaced apart from the first side in a second direction crossing the first direction in plan view.

7. The color conversion substrate of claim 6, wherein the second side is spaced apart from the third side in a direction opposite to the second direction in plan view.

8. The color conversion substrate of claim 1, wherein the third sub-pixel area has a rectangular shape.

9. The color conversion substrate of claim 1, wherein an area of the first sub-pixel area is greater than or equal to an area of the second sub-pixel area, and
wherein the area of the second sub-pixel area is greater than an area of the third sub-pixel area.

10. The color conversion substrate of claim 1, wherein the first sub-pixel area is configured to emit a first light having a red color,
wherein the second sub-pixel area is configured to emit a second light having a green color, and
wherein the third sub-pixel area is configured to emit a third light having a blue color.

11. The color conversion substrate of claim 1, wherein a center of the third sub-pixel area overlaps a center of a collective pixel area of the first to third sub-pixel areas in the first direction.

12. The color conversion substrate of claim 1, further comprising a partition wall under the substrate, and defining the first sub-pixel area, the second sub-pixel area, and the third sub-pixel area.

13. The color conversion substrate of claim 12, wherein a width of the partition wall between the first sub-pixel area and the second sub-pixel area, and a width of the partition wall between the second sub-pixel area and the third sub-pixel area, are about 5 micrometers to about 20 micrometers.

14. The color conversion substrate of claim 13, further comprising a color conversion layer below the substrate, and overlapping the first sub-pixel area, the second sub-pixel area, and the third sub-pixel area in plan view.

15. The color conversion substrate of claim 14, wherein the color conversion layer comprises:
a first color conversion pattern overlapping the first sub-pixel area;
a second color conversion pattern overlapping the second sub-pixel area; and
a transmission pattern overlapping the third sub-pixel area.

16. The color conversion substrate of claim 14, further comprising a color filter layer between the substrate and the color conversion layer.

17. The color conversion substrate of claim 16, wherein the first to third pixel areas further comprise a light-blocking area surrounding the first to third sub-pixel areas,
wherein the color filter layer comprises first to third color filter layers partially overlapping each other,
wherein the first color filter layer comprises a first color filter pattern overlapping the first sub-pixel area, and not overlapping the second color filter layer and the third color filter layer,
wherein the second color filter layer comprises a second color filter pattern overlapping the second sub-pixel area, and not overlapping the first color filter layer and the third color filter layer, and
the third color filter layer comprises a third color filter pattern overlapping the third sub-pixel area, and not overlapping the first color filter layer and the second color filter layer.

18. The color conversion substrate of claim 17, wherein an area of the first color filter pattern is greater than an area of the second color filter pattern, and
wherein the area of the second color filter pattern is greater than an area of the third color filter pattern.

19. The color conversion substrate of claim 17, wherein an area of the first color filter pattern is less than an area of the first sub-pixel area,
wherein an area of the second color filter pattern is less than an area of the second sub-pixel area, and
wherein an area of the third color filter pattern is less than an area of the third sub-pixel area.

20. A color conversion substrate comprising:
a substrate comprising a first sub-pixel area, a second sub-pixel area, and a third sub-pixel area configured to emit light of different respective colors, and spaced apart from each other in a first direction,
wherein each of the first sub-pixel area and the third sub-pixel area has a trapezoidal shape, and
wherein the second sub-pixel area is spaced from each of the first sub-pixel area and the third sub-pixel area.

21. The color conversion substrate of claim 20, wherein the first sub-pixel area, the second sub-pixel area, and the third sub-pixel area overlap each other in the first direction.

22. The color conversion substrate of claim 20, wherein the second sub-pixel area has a trapezoidal shape.

23. The color conversion substrate of claim 20, wherein each of the first sub-pixel area and the third sub-pixel area has a trapezoidal shape, a width of which becomes narrower toward a second direction crossing the first direction, and
wherein the second sub-pixel area has a trapezoidal shape, a width of which becomes wider toward the second direction.

24. A display device comprising:
a color conversion substrate comprising a first substrate comprising a first sub-pixel area, a second sub-pixel area, and a third sub-pixel area configured to emit light of different respective colors, and spaced apart from each other in a first direction; and
an array substrate comprising a second substrate facing the first substrate, and comprising light-emitting diodes on the second substrate and respectively overlapping the first to third sub-pixel areas,
wherein each of the first sub-pixel area and the second sub-pixel area has a right-angled triangle shape in which at least one of corners, other than a corner forming a right angle, is chamfered, and
wherein the third sub-pixel area has a quadrilateral shape.

25. The display device of claim 24, wherein the first sub-pixel area, the second sub-pixel area, and the third sub-pixel area overlap each other in the first direction.

26. The display device of claim 24, wherein a hypotenuse of the first sub-pixel area and a hypotenuse of the second sub-pixel area are adjacent to each other.

27. The display device of claim 24, wherein the first sub-pixel area comprises a first side and a second side that are substantially perpendicular to each other, a length of the first side being greater than or equal to a length of the second side, and
wherein the second sub-pixel area comprises a third side and a fourth side that are substantially perpendicular to each other, a length of the third side being greater than or equal to a length of the fourth side.

28. The display device of claim 27, wherein the first side and the third side are substantially parallel to each other, and
wherein the second side and the fourth side are substantially parallel to each other.

29. The display device of claim 24, wherein the third sub-pixel area has a rectangular shape.

30. The display device of claim 24, wherein the color conversion substrate further comprises:
a partition wall under the first substrate, and defining the first sub-pixel area, the second sub-pixel area, and the third sub-pixel area;
a color conversion layer below the first substrate, and overlapping the first sub-pixel area, the second sub-pixel area, and the third sub-pixel area; and
a color filter layer between the first substrate and the color conversion layer.

31. The display device of claim 30, wherein each of the first to third pixel areas further comprises a light-blocking area surrounding the first to third sub-pixel areas,
wherein the color filter layer comprises first to third color filter layers partially overlapping each other,
wherein the first color filter layer comprises a first color filter pattern overlapping the first sub-pixel area, and not overlapping the second color filter layer and the third color filter layer,
wherein the second color filter layer comprises a second color filter pattern overlapping the second sub-pixel area, and not overlapping the first color filter layer and the third color filter layer, and
wherein the third color filter layer comprises a third color filter pattern overlapping the third sub-pixel area, and not overlapping the first color filter layer and the second color filter layer.

32. The display device of claim 31, wherein the light-emitting diodes comprise:
a first light-emitting diode overlapping the first sub-pixel area;
a second light-emitting diode overlapping the second sub-pixel area; and
a third light-emitting diode overlapping the third sub-pixel area.

33. The display device of claim 32, wherein the first light-emitting diode comprises a first pixel electrode overlapping the first sub-pixel area,
wherein the second light-emitting diode comprises a second pixel electrode overlapping the second sub-pixel area, and
wherein the third light-emitting diode comprises a third pixel electrode overlapping the third sub-pixel area.

34. The display device of claim 33, wherein an area of the first pixel electrode is less than an area of the first color filter pattern,
wherein an area of the second pixel electrode is less than an area of the second color filter pattern, and
wherein an area of the third pixel electrode is less than an area of the third color filter pattern.
